(19) United States
(12) Patent Application Publication
(10) Pub. No.: US 2025/0309871 A1
(43) Pub. Date: Oct. 2, 2025

(54) HIGH-PERFORMANCE PULSED LATCH AND CLOCK GENERATION FOR PULSED LATCH ARCHITECTURES

(71) Applicant: Intel Corporation, Santa Clara, CA (US)

(72) Inventors: Amit Agarwal, Hillsboro, OR (US); Steven K. Hsu, Lake Oswego, OR (US); Ram Kumar Krishmanurthy, Portland, OR (US); Anupama A. Thaploo, Folsom, CA (US); Ganesan Iyer, Phoenix, AZ (US); Ananthakrishnan Ponnileth Rajendran, Rancho Cordova, CA (US); Bhushan Borole, Rancho Cordova, CA (US)

(21) Appl. No.: 18/618,505

(22) Filed: Mar. 27, 2024

(51) Int. Cl. H03K 3/037; G01R 31/3185

(52) U.S. Cl. CPC H03K 3/037; G01R 31/318541; G01R 31/318552

(57) ABSTRACT

A latch circuit includes a NOR gate including a first input terminal to receive a scan input signal and a second input terminal to receive a control signal. The latch circuit further includes a first transmission gate including a first input terminal coupled to an output terminal of the NOR gate, and a second input terminal and a third input terminal to receive at least one non-pulsed clock signal. The latch circuit further includes a first inverter including an input terminal to receive a data input signal. The latch circuit further includes a second transmission gate including a first input terminal coupled to an output terminal of the first inverter, and a second input terminal and a third input terminal to receive at least one pulsed clock signal.

### BACKGROUND

High-performance designs for modern microprocessors, discrete graphics, DSPs, and hardware accelerators in laptops and servers are increasingly becoming the most critical factor due to emerging applications such as artificial intelligence (AI)/machine learning, autonomous driving, security/cryptocurrency, and computer vision.

### BRIEF DESCRIPTION OF THE DRAWINGS

In the drawings, like numerals may describe the same or similar components or features in different views. Like numerals having different letter suffixes may represent different instances of similar components. Some embodiments are illustrated by way of example, and not limitation, in the figures of the accompanying drawings in which:

FIG. 1 is a block diagram of the application of pulsed latches in interconnect mesh and repeater buses, in accordance with some embodiments;

FIG. 2 is a block diagram of a global pulse generator circuit with a distributed latch, in accordance with some embodiments;

FIG. 3 is a block diagram of a local pulse generator integrated with a multi-bit pulsed latch standard cell circuit, in accordance with some embodiments;

FIG. 4 is a block diagram of a pulse generator circuit, in accordance with some embodiments;

FIG. 5A is a block diagram illustrating converting a scan latch to a pulse latch where the scan is a pulsed flip-flop (FF) with a diverged clock, in accordance with some embodiments;

FIG. 5B is a block diagram illustrating converting a scan latch to a pulse latch where the scan is a pulsed latch, in accordance with some embodiments;

FIG. 6A is a block diagram illustrating a high-performance scan pulsed latch with a keeper bypassed scan multiplexer (mux), in accordance with some embodiments;

FIG. 6B is a timing diagram of signaling associated with the high-performance scan pulsed latch of FIG. 6A, in accordance with some embodiments;

FIG. 7 is a diagram illustrating a launch off shift (LOS) mode of scan testing, in accordance with some embodiments;

FIG. 8 illustrates a diagram of the high-performance scan pulsed latch of FIG. 6A using a different Tclk2q delay for scan and data mode, in accordance with some embodiments;

FIG. 9A is a block diagram of a LOS scan test compatible scan pulsed latch, in accordance with some embodiments;

FIG. 9B is a timing diagram of signaling associated with the LOS scan test compatible scan pulsed latch of FIG. 9A, in accordance with some embodiments;

FIG. 10 is a diagram of a pipeline circuit of SHA256 message digest data path round for a bitcoin mining round, in accordance with some embodiments;

FIG. 11 is a diagram of a 3-phase latch-based clocking using non-overlapping clocks, in accordance with some embodiments;

FIG. 12 is a diagram of a clocking scheme to enable pulsed latch in back-to-back sequentials with clocking repeated after every 3 pipeline stages, in accordance with some embodiments;

FIG. 13A is a diagram of a non-pulsed skewed clock pulse generation circuit to enable a non-overlapping pulsed clock, in accordance with some embodiments;

FIG. 13B is a diagram of a toggle flip-flop for generating one or more clock signals for the pulse generation circuit of FIG. 13A, in accordance with some embodiments;

FIG. 14 is a diagram of a pulsed latch with a NAND pulse generator circuit and an XOR pulse generator circuit generating clock pulses at both clock edges, in accordance with some embodiments;

FIG. 15A is a diagram of a non-pulsed skewed clock pulse generation circuit to enable a non-overlapping pulsed clock with NAND-based pulse generators, in accordance with some embodiments;

FIG. 15B is a diagram of a toggle flip-flop for generating one or more clock signals for the pulse generation circuit of FIG. 15A, in accordance with some embodiments;

FIG. 16 is a flow diagram of an example method for configuring a pulsed latch circuit, in accordance with some embodiments; and

FIG. 17 illustrates a block diagram of an example machine upon which any one or more of the operations/techniques (e.g., methodologies) discussed herein may perform.

### DETAILED DESCRIPTION

The following detailed description refers to the accompanying drawings. The same reference numbers may be used in different drawings to identify the same or similar elements. In the following description, for purposes of explanation and not limitation, specific details are set forth, such as particular structures, architectures, interfaces, techniques, etc., to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail.

The following description and the drawings sufficiently illustrate specific embodiments to enable those skilled in the art to practice them. Other embodiments may incorporate structural, logical, electrical, process, and other changes. Portions and features of some embodiments may be included in or substituted for those of other embodiments. Embodiments outlined in the claims encompass all available equivalents of those claims.

As used herein, the term “chip” (or die) refers to a piece of a material, such as a semiconductor material, that includes a circuit, such as an integrated circuit or a part of an integrated circuit. The term “memory IP” indicates memory intellectual property. The terms “memory IP,” “memory device,” “memory chip,” and “memory” are interchangeable.

The term “a processor” configured to carry out specific operations includes both a single processor configured to carry out all of the operations (e.g., operations or methods disclosed herein) as well as multiple processors individually configured to carry out some or all of the operations (which may overlap) such that the combination of processors carry out all of the operations.

High-performance designs for modern microprocessors, discrete graphics, DSPs, and hardware accelerators in laptops and servers are increasingly becoming a critical factor due to emerging applications such as AI/machine learning, autonomous driving, security/cryptocurrency, and computer vision. An essential standard cell and a fundamental building block of any digital integrated circuit is the flip-flop, which is required to store state in any sequential logic, and its delay constitutes ˜10%-20% of cycle time in a high-performance design. A pulsed latch as a sequential element has been shown to provide better delay as well as reduced power compared to flip-flop circuits.

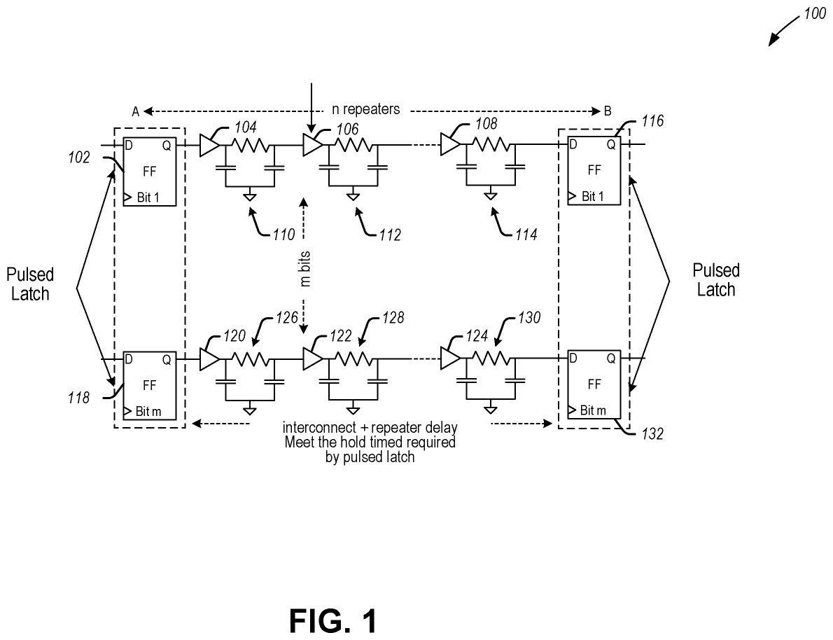

The high-performance pulsed latch circuits are more applicable in current/future frequency-constrained server interconnect mesh and graphics repeater buses. These interconnect circuits send data from A to B with a fixed interconnect and repeater delay and, by construction, meet the extra hold time required by pulsed latches (e.g., as illustrated in FIG. 1).

FIG. 1 is a block diagram 100 of the application of pulsed latches in interconnect mesh and repeater buses, in accordance with some embodiments. Referring to FIG. 1, a first bus includes flip-flops 102 and 116 and buffers (or repeaters) 104, 106, and 108 coupled to corresponding interconnects 110, 112, and 114. A second bus includes flip-flops 118 and 132 and buffers (or repeaters) 120, 122, and 124 coupled to corresponding interconnects 126, 128, and 130.

Sequential delay constitutes almost 20-30% of the cycle time for such high-performance server mesh, e.g., 4 GHZ (e.g., a time period of 250 ps) mesh with 50 ps-70 ps sequential delay. Having a lower delay sequential (e.g., a pulsed latch) can help meet the frequency target and can enable more routing tracks by wire optimization at iso-frequency to achieve higher bandwidth. In this regard, flip-flops 102, 116, 118, and 132 can be replaced by pulsed latches in some aspects. A pulsed latch can also be used as a means to fix outlier maximum delay paths, helping to bring those paths closer to the overall timing wall while at the same time trying to keep the number of pulse latches inserted low and the associated pulse generator dynamic power cost manageable.

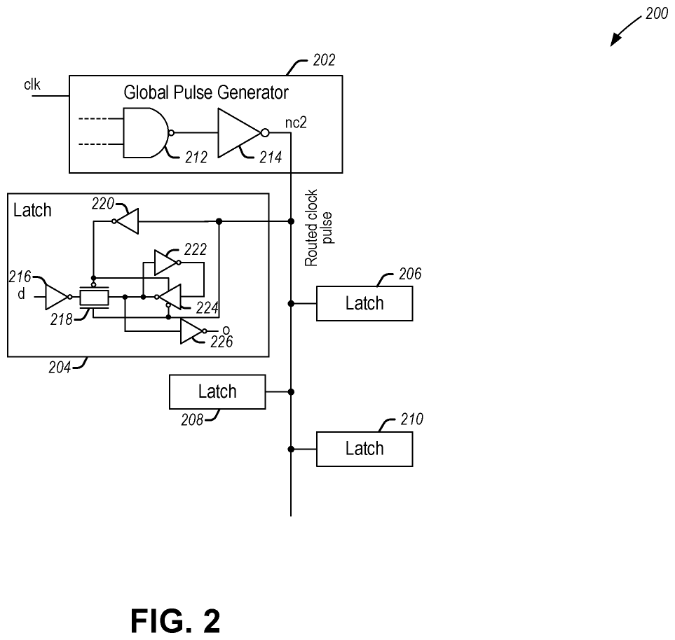

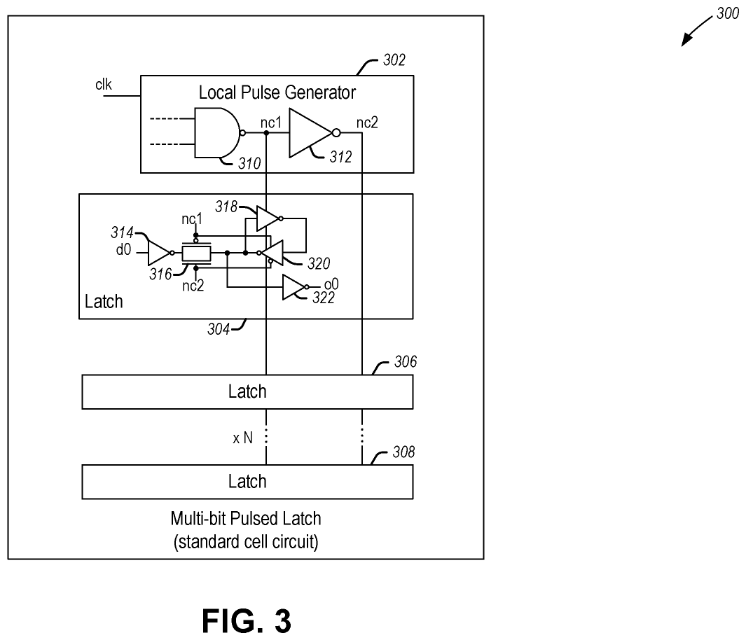

Pulse latches are functionally equivalent to a flip-flop and are designed using a latch, which is driven by a small clock pulse derived from the main clock using a pulse generator circuit. In some aspects, a pulse generator circuit can either be shared globally (e.g., as illustrated in FIG. 2), where the generated pulsed clock is routed to multiple latches, or can be local to a multi-bit latch (e.g., as illustrated in FIG. 3) and integrated as part of a standard cell circuit. Today's CAD tools can easily insert multi-bit flip-flops at the block level and have been commonly done in all products, both internally and externally.

FIG. 2 is a block diagram 200 of a global pulse generator circuit with a distributed latch, in accordance with some embodiments. Referring to FIG. 2, the global pulse generator 202 can be configured to supply a pulsed clock (or a clock pulse) to multiple latches such as latches 204, 206, 208, and 210.

In some aspects, the global pulse generator 202 includes a NAND gate 212 coupled to an inverter 214. In some aspects, the latches (e.g., latch 204) include an inverter 216 coupled to the data path (d), a transmission gate 218 coupled to a tri-state inverter 224, and inverters 220, 222, and 226.

FIG. 3 is a block diagram of a local pulse generator integrated with a multi-bit pulsed latch cell circuit 300, in accordance with some embodiments. Referring to FIG. 3, the multi-bit pulsed latch cell circuit 300 includes a local pulse generator 302 configured to supply a pulsed clock (or a clock pulse) to multiple latches such as latches 304, 306, . . . , 308.

In some aspects, the local pulse generator 302 includes a NAND gate 310 coupled to an inverter 312. In some aspects, the latches (e.g., latch 304) include an inverter 314 coupled to the data path and a transmission gate 316 coupled to a tri-state inverter 320 and inverters 318 and 322.

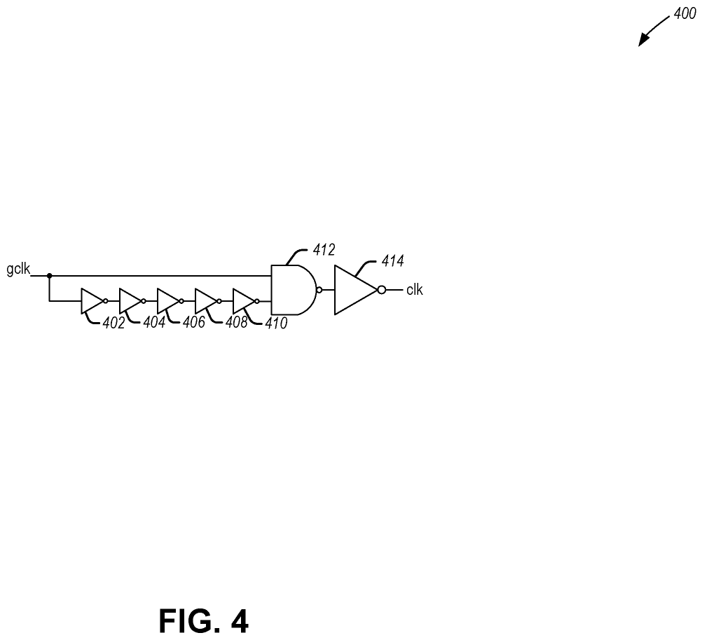

FIG. 4 is a block diagram of a pulse generator circuit 400, in accordance with some embodiments. Pulse generator circuit 400 uses a delayed clock with inverters (e.g., inverters 402, 404, 406, 408, and 410) followed by a NAND gate 412 and inverter 414.

Increased complexity of current designs can necessitate increased scan coverage. Hence, each latch/flip-flop can include testability circuit hooks (e.g., scan capabilities such as a scan chain), which can be used for testing. In some aspects, two types of scan test circuits can be implemented in a sequential (e.g., a bus line or other circuit topology): (a) a Level Sensitive Scan Design (LSSD) and (b) a Mux-D scan design. Pulsed latch circuits that use LSSD-based scans are not Mux-D scan compatible. The Mux-D-based scan has become more prevalent due to its low area/design complexity overhead.

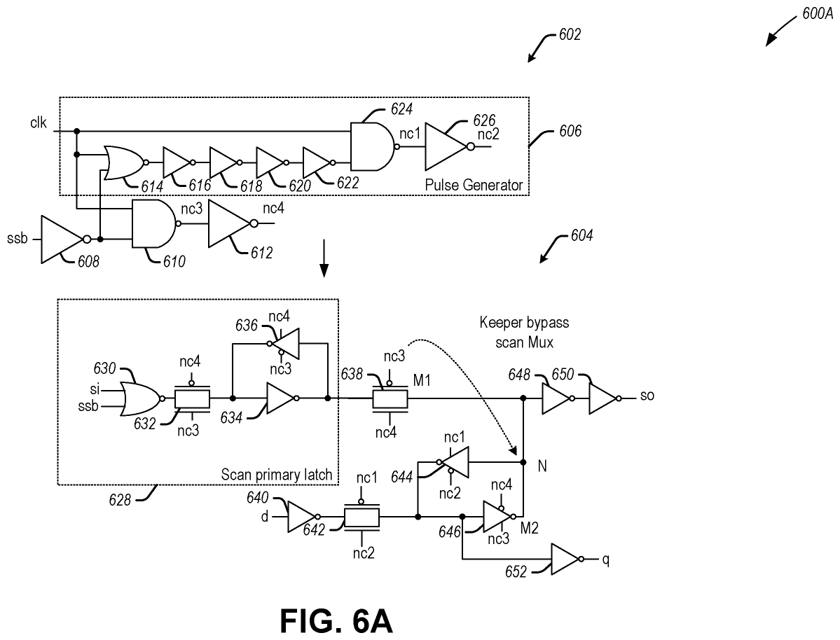

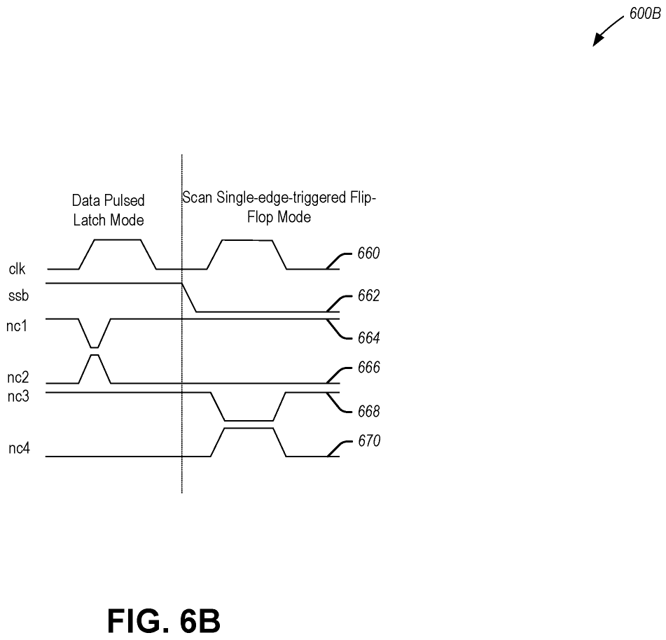

The disclosed techniques (e.g., FIGS. 6A-9B) include a Mux-D scan pulsed latch standard cell circuit, which enables a scan path that acts as a single edge-triggered (non-pulsed) flip-flop, which is compatible with the Mux-D scan methodology. The disclosed scan pulsed latch also eliminates the scan multiplexer (mux) delay overhead using a gated clock and a keeper bypassed scan mux. The disclosed techniques also include an alternative option to make proposed circuits Launch-off-Shift (LOS) scan test compatible at the cost of scan mux delay overhead.

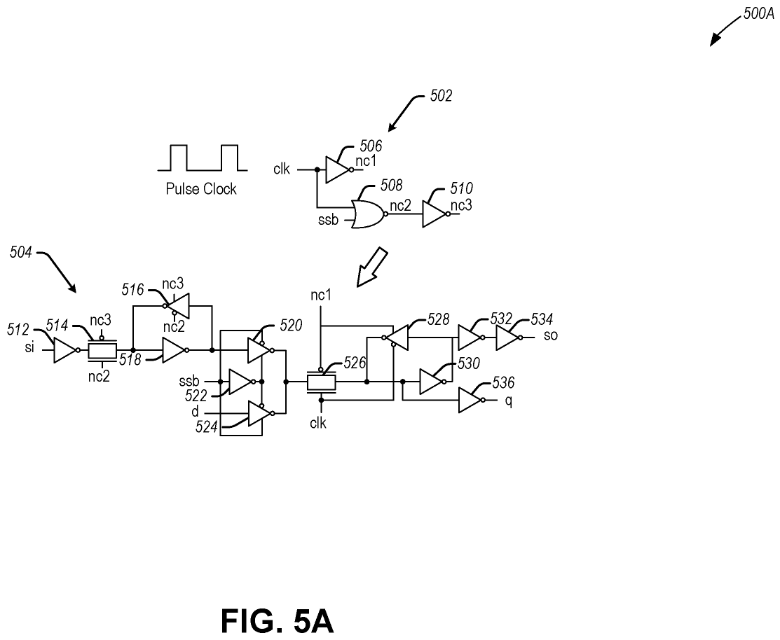

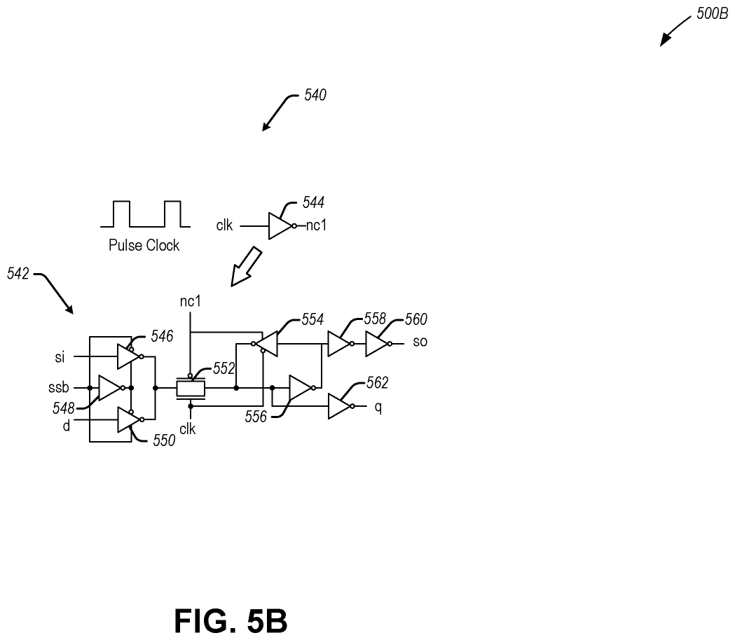

FIG. 5A and FIG. 5B show two options for converting a conventional latch (non-pulsed) with a Mux-D scan to a pulsed scan latch.

FIG. 5A is a block diagram illustrating converting a scan latch to a pulse latch where the scan is a pulsed flip-flop (FF) with a diverged clock, in accordance with some embodiments. Referring to FIG. 5A, the pulse latch 500A includes a pulse clock generator 502 and latch 504.

The pulse clock generator 502 includes inverters 506 and 510 and a NOR gate 508. The pulse clock generator 502 generates clock signals nc1, nc2, and nc3.

Latch 504 includes inverters 512, 518, 522, 530, 532, 534, and 536. Latch 504 also includes transmission gates 514 and 526 and tri-state inverters 516, 520, 524, and 528.

FIG. 5B is a block diagram illustrating converting a scan latch to a pulse latch where the scan is a pulsed latch, in accordance with some embodiments. Referring to FIG. 5B, the pulse latch 500B includes a pulse clock generator 540 and latch 542.

The pulse clock generator 540 includes an inverter 544 generating clock signal nc1.

Latch 542 includes inverters 548, 556, 558, 560, and 562. Latch 542 also includes transmission gate 552 and tri-state inverters 546, 550, and 554.

As illustrated in FIG. 5A, a clock pulse is supplied to the clk input, converting the latch to a pulsed latch. However, with this topology, the scan operation is a pulsed FF. Moreover, during scan mode, the circuit has a diverged clock between a primary and a secondary latch, which may result in internal min-delay race/scan stitch hold failure. As illustrated in FIG. 5B, the primary scan latch can be removed, and the scan mux is kept, removing the diverged clock issue. However, in this design, the scan operation is also a pulsed latch, which uses a large number of scan minimum (min) delay buffers to meet scan stitching hold time. Moreover, both options in FIG. 5A and FIG. 5B have a mux delay overhead in the normal data mode of operation.

FIG. 6A is a block diagram 600A illustrating a high-performance scan pulsed latch 602 with a keeper bypassed scan multiplexer (mux), in accordance with some embodiments. Referring to FIG. 6A, the scan pulsed latch 602 includes a pulse generator 606 and a latch circuit 604.

The pulse generator 606 generates pulse clocks nc1 and nc2 using a NOR gate 614, inverters 616, 618, 620, 622, and 626, and a NAND gate 624. The pulse generator 606 also generates non-pulse clocks nc3 and nc4 using NAND gate 610 and inverters 608 and 612.

The latch circuit 604 includes a scan primary latch circuit 628, which includes NOR gate 630, transmission gate 632, inverter 634, and tri-state inverter 636. The latch circuit 604 also includes inverters 640, 652, 648, and 650, transmission gates 642 and 638, and tri-state inverters 644 and 646.

FIG. 6B is a timing diagram 600B of signaling 660, 662, 664, 666, 668, and 670 associated with the high-performance scan pulsed latch of FIG. 6A, in accordance with some embodiments.

FIGS. 6A-6B illustrate a high-performance Mux-D scan pulsed latch with keeper bypassed scan mux. This design implements a clock pulse generator, which is gated with an SSB signal to force its clock output nc1 to “1” and nc2 to “0” in scan mode. Scan clock signals (nc3 and nc4) are derived on the side using a NAND and an inverter, which are deactivated during regular pulsed latch operation using an SSB signal. The nc3 and nc4 are derived before pulse clock generation and switched to a conventional clock (non-pulsed) during scan mode.

FIG. 6A also illustrates a pulse generator circuit using a delayed clock with inverters followed by a NAND gate, but this pulse generator can be configured differently as well. A primary latch is added to the scan path, which is clocked by nc3 and nc4. This scan primary latch is bypassed into the keeper side path of the pulsed latch. This bypassed scan path adds a secondary latch transmission gate M1 and converts the forward inverter of the pulse latch keeper into a tri-state (M2); both are driven by scan clock nc3 and nc4.

During regular pulsed latch operation (SSB=1), nc3 is forced to “1” and nc4 is forced to “0”, blocking the transmission gate M1 and making tristate M2 act like an inverter, and do not contribute towards power. The circuit operates as regular pulses latch through input “d” using generated clock pulses on nc1/nc2. This design bypasses the scan mux to the keeper side path and hence does not have a scan mux delay overhead. Scan input is gated using a NOR gate with SSB to prevent data switching in the primary scan latch during regular pulse latch operation.

In scan mode (SSB=0), the pulse generator is gated by SSB, which forces nc1 to “1” and nc2 to “0”. The nc3 and nc4 are active and act like conventional scan clock signals. The input “d” path is disabled, and the tri-state keeper connected to nc1 and nc2 acts like an inverter. The scan path controlled by nc3 and nc4 operates as a single-edge-triggered flip-flop and is fully compatible with the Mux-D scan design. The scan operation is robust and does not have any diverged clock between the primary and secondary latch.

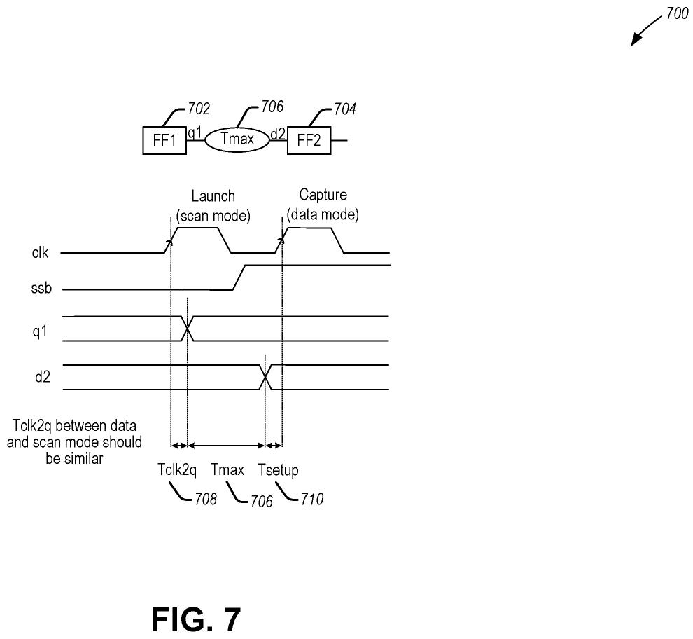

Some products are configured based on maximum (max) path testing using the Launch-off-Shift (LOS) mode of scan (e.g., as illustrated in FIG. 7).

FIG. 7 is a diagram 700 illustrating a launch off shift (LOS) mode of scan testing, in accordance with some embodiments. Referring to FIG. 7, delay Tmax 706 can be configured between flip-flops 702 and 704. Additional delays Tclk2q 708 and setup delay Tsetup 710 can also be present.

In the LOS mode of the scan test, SSB (scan select) changes at speed. The data is launched in scan mode by the first flip-flop 702 and captured in data mode by the second flip-flop 704. This tests the frequency, which includes Tclk2q of launching flip-flop, Tmax of the logic, and setup of the capturing flip-flop. Since during the test, launching flip-flop is in scan mode, while in the field, it will be in data mode, this speed test requires Telk2q in both data and scan mode to be similar to detect any in-field speed failure.

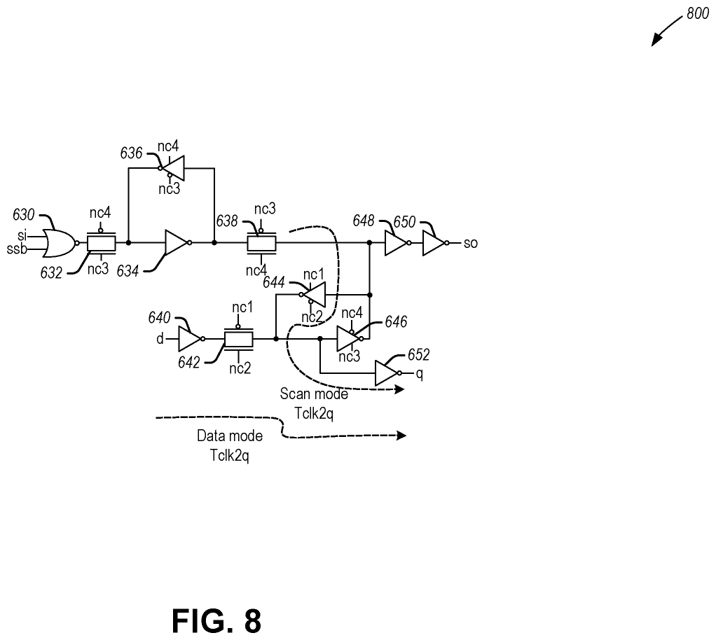

FIG. 8 illustrates diagram 800 of the high-performance scan pulsed latch of FIG. 6A using a different Tclk2q delay for scan and data mode, in accordance with some embodiments. The high-performance mux-D scan pulsed latch proposed in FIGS. 6A-6B has a different tclk-2-q delay in scan and data mode (e.g., as illustrated in FIG. 8). The difference in this tclk-2-q delay makes this circuit incompatible with the LOS mode of scan testing (e.g., the FIGS. 6A-6B circuit can be configured for products not requiring LOS testing).

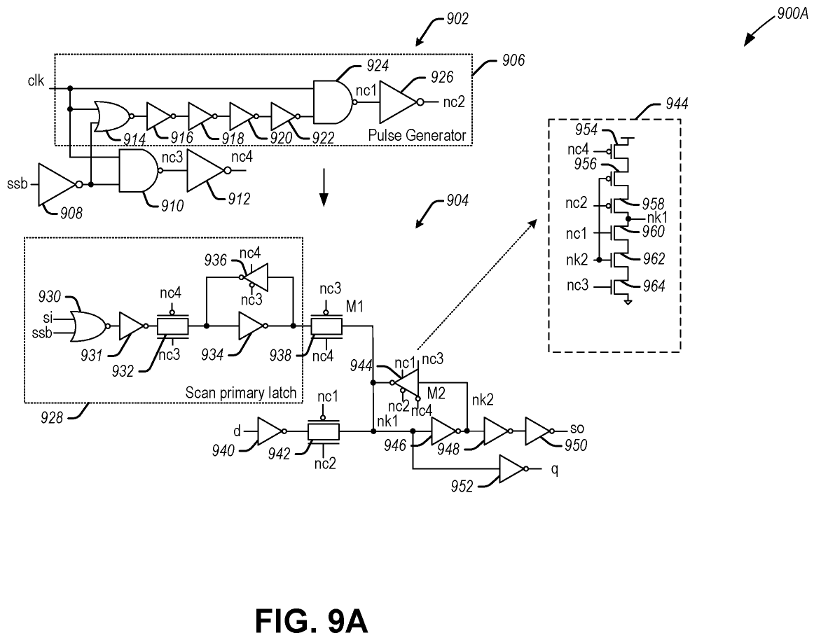

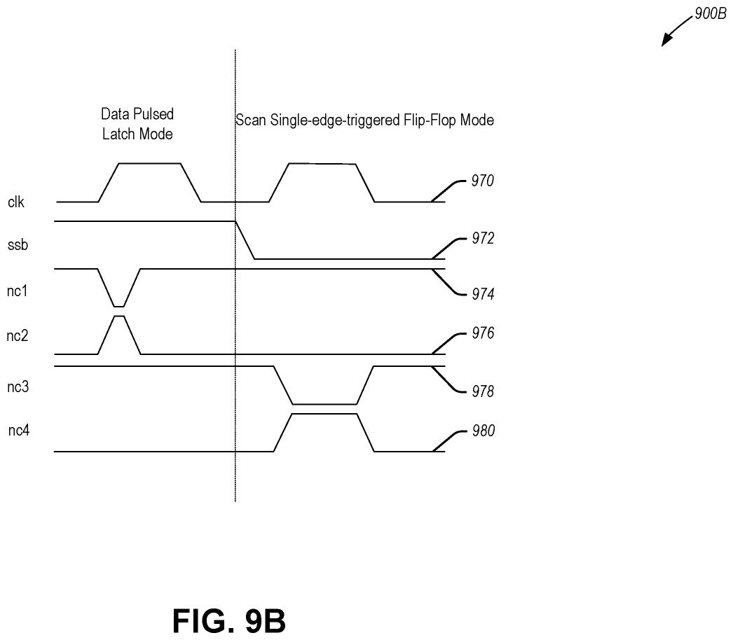

FIG. 9A is a block diagram 900A of a LOS scan test compatible scan pulsed latch, in accordance with some embodiments. Referring to FIG. 9A, the scan pulsed latch 902 includes a pulse generator 906 and a latch circuit 904.

The pulse generator 906 generates pulse clocks nc1 and nc2 using a NOR gate 914, inverters 916, 918, 920, 922, and 926, and a NAND gate 924. The pulse generator 906 also generates non-pulse clocks nc3 and nc4 using NAND gate 910 and inverters 908 and 912.

The latch circuit 904 includes a scan primary latch circuit 928, which includes NOR gate 930, transmission gate 932, inverters 934 and 931, and tri-state inverter 936. The latch circuit 904 also includes inverters 940, 952, 946, 948, and 950, transmission gates 942 and 938, and multi-state inverter 944.

In some aspects, the multi-state inverter 944 is configured with PMOS transistors 954, 956, and 958 and NMOS transistors 960, 962, and 964.

FIG. 9B is a timing diagram 900B of signaling 970, 972, 974, 976, 978, and 980 associated with the LOS scan test compatible scan pulsed latch of FIG. 9A, in accordance with some embodiments.

FIG. 9A shows another version of the mux-D scan pulsed latch circuit of FIG. 6A, which is LOS scan test compatible and has a similar Tolk2q delay for both data and scan mode. In this design, the primary scan latch is muxed with pulsed latch data input through the secondary scan latch transmission gate M1. Since nc1/nc2 switch during normal pulsed latch mode of operation, while nc3/nc4 switch during scan operation, one mux path is enabled during normal mode or scan mode of operation. The pulse latch keeper M2 is triple-stacked and can be interrupted with either nc1/nc2 or nc3/nc4. The proposed circuit operates as a pulsed latch during data mode and a single-edge-triggered flip-flop during scan mode, making it compatible with the mux-D scan methodology. This mux-D scan pulsed latch circuit has a similar Tclk2q delay for both data and scan mode of operation, which makes it compatible with the LOS mode of testing at the cost of scan mux delay overhead.

In some embodiments, the pulse latch circuits disclosed above (e.g., in reference to FIGS. 1-9B) can be used in connection with non-pulsed skewed clock generation circuits to enable non-overlapping pulsed clock configurations for back-to-back pulse latches.

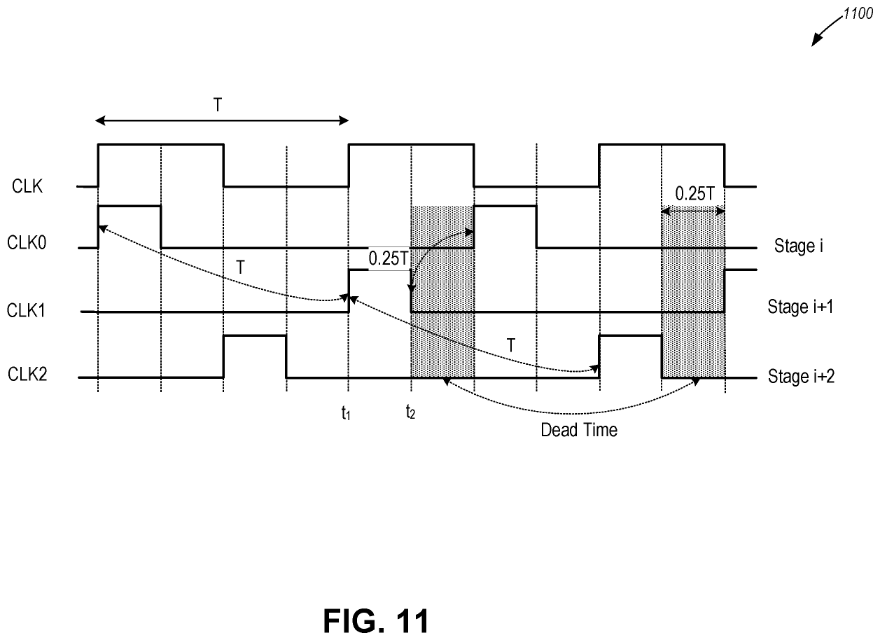

Non-overlapping clock schemes incur performance penalties because of hold time requirements (one example is shown in FIG. 11). In some aspects, the min delay buffers insertion can be prohibitive to meeting hold margin in energy/area constraint applications like Bitcoin, which has a lot of back-to-back sequential paths. The disclosed techniques present a non-overlap clocking scheme/circuit that solves performance issues in previously proposed non-overlapping clocking without inserting min delay buffers.

The disclosed techniques can be applicable to any pulse generator discussed herein. The disclosed techniques include a clock skew generation circuit to enable non-overlapping pulsed clocks. In some aspects, the skewed clock generation circuit takes the clock pulse generated from the pulse generator (any pulse generator circuit) of a subsequent (e.g., second) pipeline stage as an input. Using the falling edge (closing) of this input clock pulse, the proposed circuit generates a skewed clock signal, which is not pulse and hence can be distributed without any pulse evaporation. In some aspects, the first pipeline stage pulse generator circuit uses this skewed clock to generate a non-overlapped clock pulse.

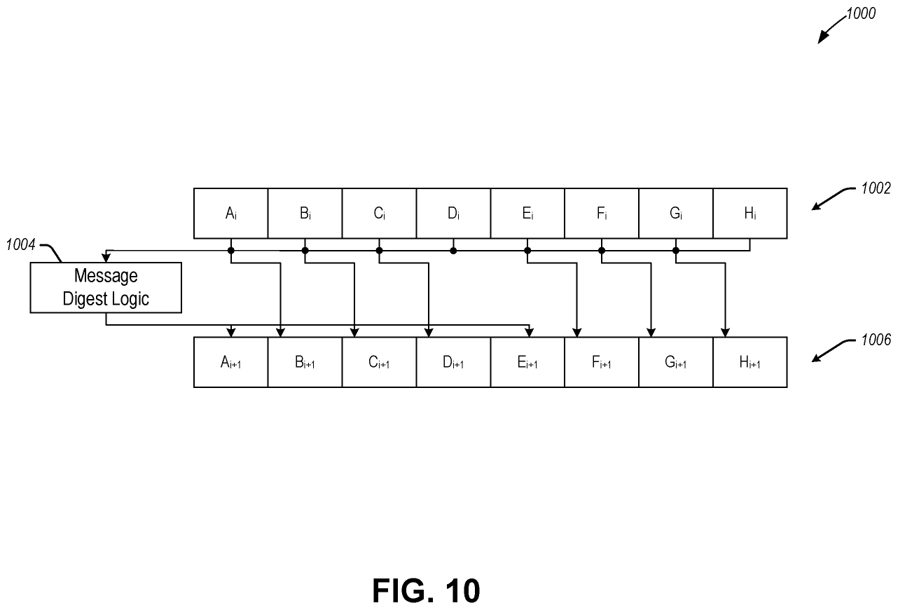

Bitcoin is the most popular digital currency used for peer-to-peer transactions, eliminating the need for intermediate financial institutions by guaranteeing authenticity and user anonymity using digital signatures. The SHA-256-based hashing operation is the most significant recurring cost a miner incurs in the process of creating a Bitcoin. Therefore, there is a strong motivation for developing energy-efficient hardware accelerators that reduce the energy consumed by the mining computations. A bitcoin message digest data path is shown in FIG. 10.

FIG. 10 is a diagram 1000 of a pipeline circuit of SHA-256 message digest data path round for a bitcoin mining round, in accordance with some embodiments. Referring to FIG. 10, inputs from processing pipeline 1002 are used by the message digest logic 1004. Inputs from processing pipeline 1002 and the message digest logic 1004 are used in the processing pipeline 1006.

Referring to FIG. 10, the two-timing critical paths to compute outputs Ai+1 and Ei+1 get the inputs from 8×32-bit registers A-to-H. In a conventional data path, the sequencing logic in the pipeline stages is implemented using flip-flops. The flip-flop-based design consumes 50% of the Bitcoin mining data path. These flip-flops also result in high clock power since they have 100% clock activity. Also, in the message digest data path, six out of eight 32b flip-flops are back-to-back doing shift operations between consecutive rounds, resulting in a large number of potential min delay paths per round and hence requiring a large number of min delay buffers.

In some aspects, to reduce the area and power overhead of the flip-flops, a latch-based design can be configured using a 3-phase non-overlapping clock-based clocking scheme. However, this scheme incurs performance penalties because of the hold time requirement. The disclosed techniques include a non-pulsed skewed clock signal generation circuit to enable nonoverlapping pulsed clock-based back-to-back pulse latch design in the Bitcoin mining accelerator. This skewed clock generation circuit takes the clock pulse generated from the pulse generator (any pulse generator circuit) of the second pipeline stage as an input. Using the falling edge (closing) of this input clock pulse, the proposed circuit generates a skewed clock signal, which is not pulse and hence can be distributed without any pulse evaporation. The first pipeline stage pulse generator circuit uses this skewed clock to generate a non-overlapped clock pulse. Since this technique enables latch-based design, it reduces area and power compared to flip-flop-based design. A pulsed latch clocking scheme with a min delay blocker is presented to handle the back-to-back sequential paths in the Bitcoin mining data path without impacting performance/throughput and eliminating min delay buffers. This technique keeps the critical data path latches (e.g., A and E, with min delay margin) on the same main clock pulse at all pipeline stages and hence does not impact the overall hash throughput.

Conventionally, the sequencing logic in the Bitcoin mining data path pipeline stages is implemented using flip-flops. This flip-flop-based design consumes 50% of the Bitcoin mining data path area. These flip-flops also result in high clock power since the Bitcoin application has 100% clock activity. In the message digest data path, six out of eight 32b flip-flops are back-to-back doing shift operations between consecutive rounds, resulting in a large number of potential min delay paths per round and hence requiring a large number of min-delay buffers in the previous flip-flop-based design.

FIG. 11 is a diagram 1100 of a 3-phase latch-based clocking using non-overlapping clocks, in accordance with some embodiments. FIG. 11 illustrates a 3-phase latch-based clocking scheme that uses nonoverlap clocks to enable latches. This clocking scheme, using nonoverlap clocks, enables a latch-based design with a 0.25×T margin for min-delay paths, reducing excessive clock power/area consumed by flip-flops and eliminating min-delay buffers. However, the no-overlap region of clocks introduces dead time in each pipeline stage, impacting performance/overall hash throughput.

The disclosed techniques include a non-pulsed skewed clock signal generation circuit to enable nonoverlapping pulsed clock-based back-to-back pulse latch design in the Bitcoin mining accelerator. This skewed clock generation circuit takes the clock pulse generated from the pulse generator (any pulse generator circuit) of the subsequent (e.g., second) pipeline stage as an input. Using the falling edge (closing) of this input clock pulse, the proposed circuit generates a skewed clock signal, which is not pulse and hence can be distributed without any pulse evaporation. The first pipeline stage pulse generator circuit uses this skewed clock to generate a non-overlapped clock pulse. Since this technique enables latch-based design, it reduces area and power compared to flip-flop-based design. A pulsed latch clocking scheme with a min-delay blocker is presented to handle the back-to-back sequential paths in the Bitcoin mining data path without impacting performance/throughput and eliminating min delay buffers. This technique keeps the critical data path latches (e.g., A and E with min delay margin) on the same main clock pulse at all pipeline stages and hence does not impact the overall hash throughput.

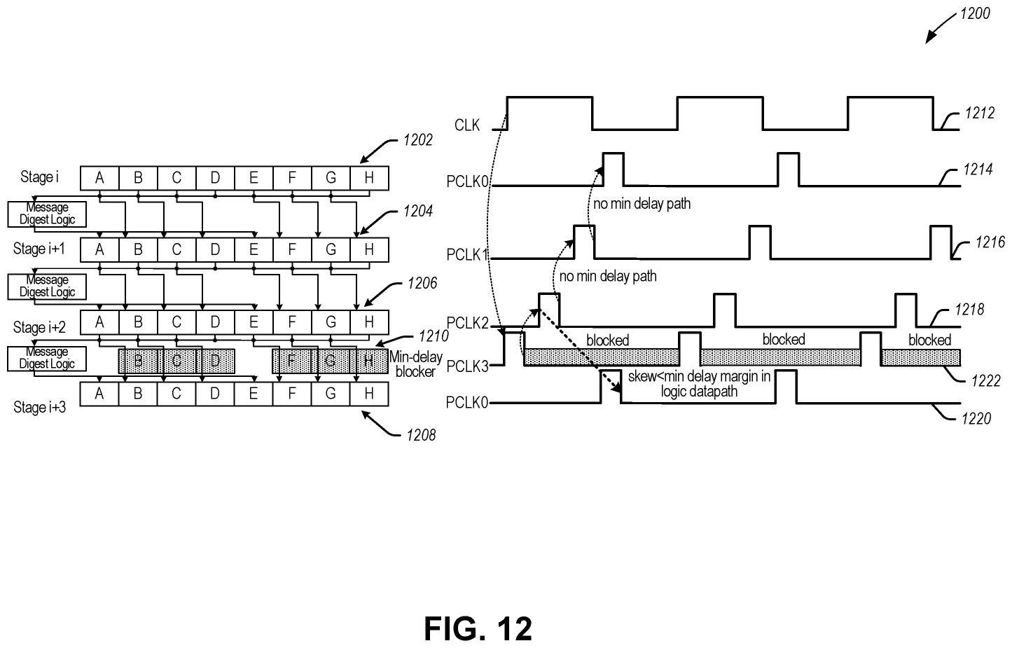

To handle the significant number of back-to-back sequential paths in the Bitcoin mining data path without impacting performance/throughput, the disclosed techniques can be based on the clocking scheme illustrated in FIG. 12.

FIG. 12 is diagram 1200 of a clocking scheme to enable pulsed latch in back-to-back sequentials with clocking repeated after every 3 pipeline stages, in accordance with some embodiments. Referring to FIG. 12, processing pipeline stages 1202, 1204, 1206, and 1208 can be configured based on corresponding clock timing diagrams 1214, 1216, 1218, and 1220. In some aspects, a min-delay blocker processing stage 1210 is used with a corresponding clock timing diagram 1222. In some aspects, the corresponding clocks in clock timing diagrams 1214-1222 are generated based on a clock signal associated with a clock timing diagram 1212.

In some aspects, the FIG. 12 scheme employs non-overlapping clock pulses between back-to-back sequential paths. The clock pulse to the first pipeline stage in back-to-back sequentials is launched after the closing of the second pipeline stage pulse clock to avoid min delay buffer insertion. Subsequently, the clock pulses of previous pipeline stages are delayed from the next pipeline stage clock. Finally, clocking is repeated after a fixed number of pipeline stages (e.g., three pipeline stages in FIG. 12) by inserting a min delay latch blocker. This min-delay latch blocker is clocked by the earliest pulse clock (PCLK3) compared to all other pipeline stages pulse clocks (PCK0-PCLK2). The critical data path latches (e.g., A and E, with min delay margin) are driven by the same main clock pulse (PCLK0) in all pipeline stages and, hence, do not impact the overall hash performance/throughput. The critical data path latches can be driven by the same clock only if the clock skew between the main clock (PLCK0) and the earliest pipeline stage clock (PCLK2) is less than the min delay margin available in the message digest logic. This min delay margin and skew between the non-overlapping pulse clocks constrains the number of pipeline stages after which the clocking scheme needs to be repeated (e.g., FIG. 12 illustrates the clocking repeated after every 3 pipeline stages).

Referring to FIG. 12, PCLK3 is the first pulsed clock derived from the main clock (CLK). This pulsed clock PCLK3 is fed to the min-delay blocker processing stage 1210 (e.g., latches that act as a pipeline stage) to reset the clocking scheme.

In the following figures, “Pipeline 3” can refer to the min-delay blocker processing stage 1210, whose clock is generated based on the main clock signal. After Pipeline 3 clock is generated, it can be used to generate the clocks of the preceding pipelines (e.g., Pipeline 2, Pipeline 1, and Pipeline 0).

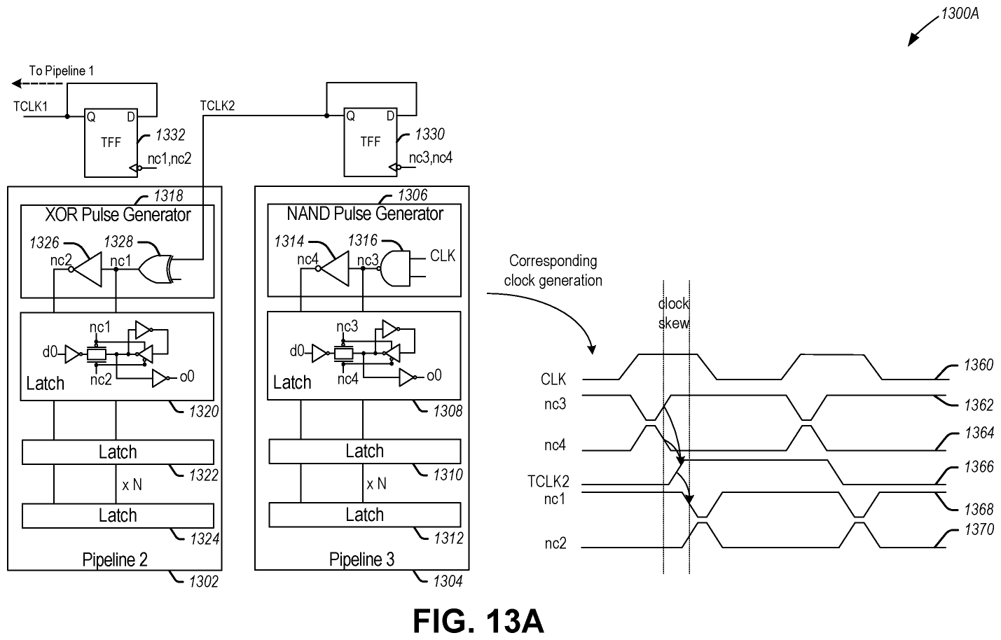

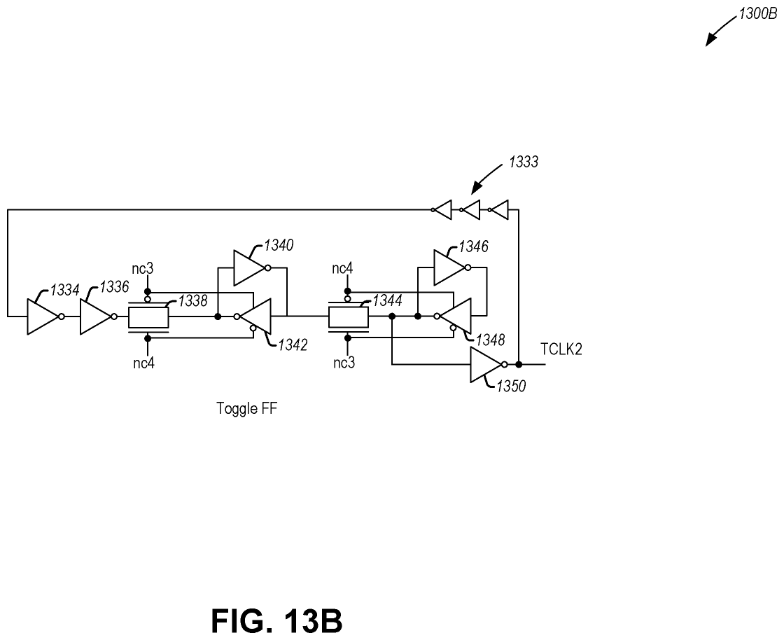

FIG. 13A is a diagram 1300A of a non-pulsed skewed clock pulse generation circuit to enable a non-overlapping pulsed clock, in accordance with some embodiments. Referring to FIG. 13A, processing pipeline 1304 (e.g., pipeline 3) includes a NAND pulse generator 1306 generating clock signals nc3 and nc4 for latches 1308, 1310, . . . , 1312. The NAND pulse generator 1306 includes an inverter 1314 and a NAND gate 1316.

Processing pipeline 1302 (e.g., pipeline 2) includes an XOR pulse generator 1318 generating clock signals nc2 and nc1 for latches 1320, 1322, . . . , 1324. The XOR pulse generator 1318 includes an inverter 1326 and an XOR gate 1328.

Pipeline 3 is configured with a toggle flip-flop (TFF) 1330 to generate clock TCLK2 communicated to pipeline 2. Similarly, pipeline 2 is configured with a TFF 1332 to generate clock TCLK1 communicated to pipeline 1. An example TFF diagram is illustrated in FIG. 13B.

FIG. 13A also illustrates corresponding timing diagrams 1360, 1362, 1364, 1366, 1368, and 1370 of the clock signals used or generated by pipeline 3 and pipeline 2.

FIG. 13B is a diagram of a toggle flip-flop 1300B for generating one or more clock signals for the pulse generation circuit of FIG. 13A, in accordance with some embodiments. Referring to FIG. 13B, TFF 1300B (which can be the same as TFF 1330 or TFF 1332) includes inverters 1333, 1334, 1336, 1340, 1346, and 1350, transmission gates 1338 and 1344, and tri-state inverters 1342 and 1348.

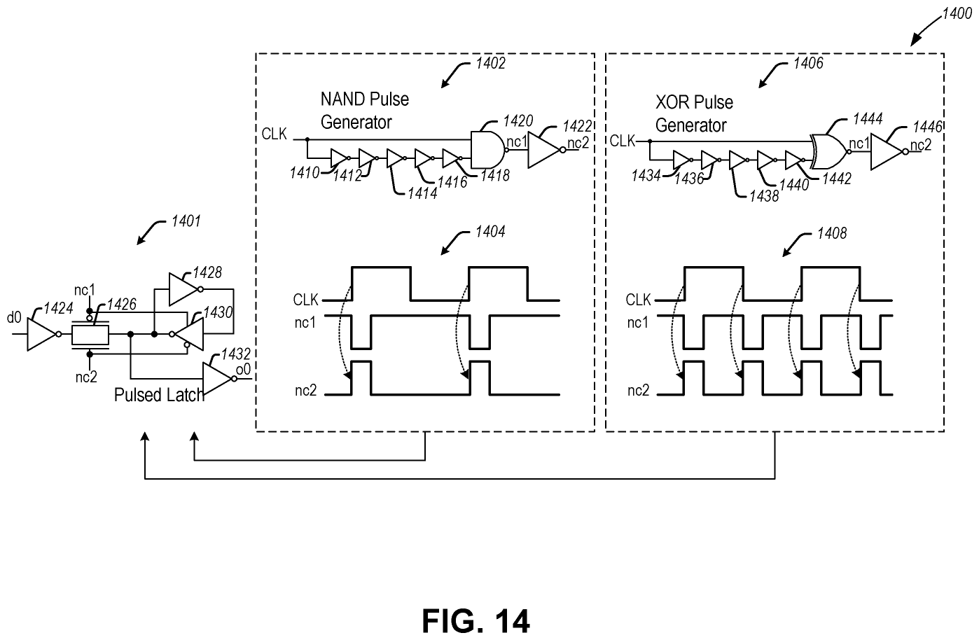

FIG. 13A and FIG. 13B illustrate a proposed non-pulsed skewed clock signal generation circuit to enable nonoverlapping pulsed clock-based back-to-back pulse latch design in a Bitcoin mining accelerator. The skewed clock is used to generate non-overlapping clock pulses. The pulse generator used in the figures can be any NAND or XOR-based pulse generator circuit (example pulse generator circuits are shown in FIG. 14). In FIGS. 13A-13B, the clock pulse generated from the NAND pulse generator of the second pipeline stage not only drives the pulsed latches but also drives the clock pins (nc3, nc4) of a falling edge toggle flip-flop. The toggle flip-flop toggles after the falling edge of the clock pulse (nc4), generating a rising/falling edge transition on signal TCLK2. The TCLK2 signal acts as a skewed clock signal, which transitions after the falling edge of the clock pulse (closing edge of the pulsed latch). The signal TCLK2 is distributed to the previous pipeline stage (e.g., pipeline 2). Since this signal is not pulsed, it can be distributed without any pulse evaporation, which exists in distributing clock pulses. The first latch in the flip-flop toggle needs to be able to write data within the clock pulse, which is the same delay constraint as required by pulse latches; hence, the toggle flip-flop operation is robust by design. The skewed clock TCLK2 is fed to an XOR-based pulse generator, which provides a pulsed clock to the first pipeline stage pulse latches. The XOR pulse generator creates clock pulses at both the rising and falling edge of the skewed TCLK2 signal, generating a pulse clock for pipeline stage 1, which opens after the closing of the pipeline stage 2 clock pulse, generating non-overlapping clock pulses. Subsequently, the pipeline stage 2 clock pulse is fed to another toggle FF, generating TCLK1 for the previous pipeline stage 1.

FIG. 14 is a diagram 1400 of a pulsed latch with a NAND pulse generator circuit and/or an XOR pulse generator circuit generating clock pulses at both clock edges, in accordance with some embodiments. Referring to FIG. 14, pulsed latch 1401 includes inverters 1424, 1428, and 1432, transmission gate 1426, and tri-state inverter 1430. In some aspects, pulsed latch 1401 can be clocked by NAND pulse generator 1402 and/or XOR pulse generator 1406.

In some aspects, the NAND pulse generator 1402 generates pulse clock signals nc1 and nc2 associated with clock timing diagram 1404 using inverters 1410, 1412, 1414, 1416, 1418, and 1422, and NAND gate 1420.

In some aspects, the XOR pulse generator 1406 generates pulse clock signals nc1 and nc2 associated with clock timing diagram 1408 using inverters 1434, 1436, 1438, 1440, 1442, and 1446, and XOR gate 1444.

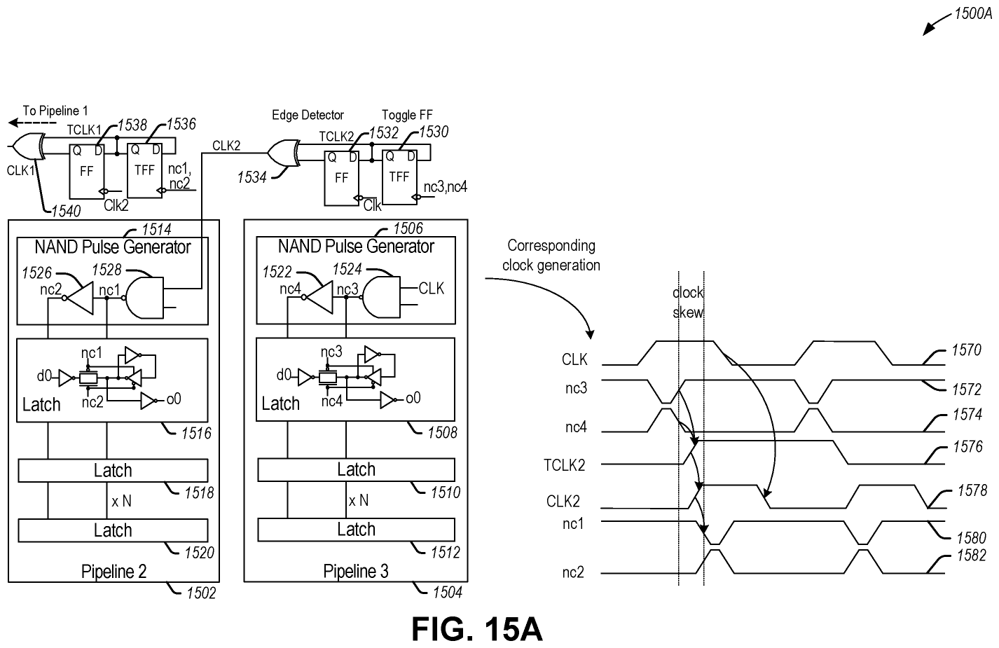

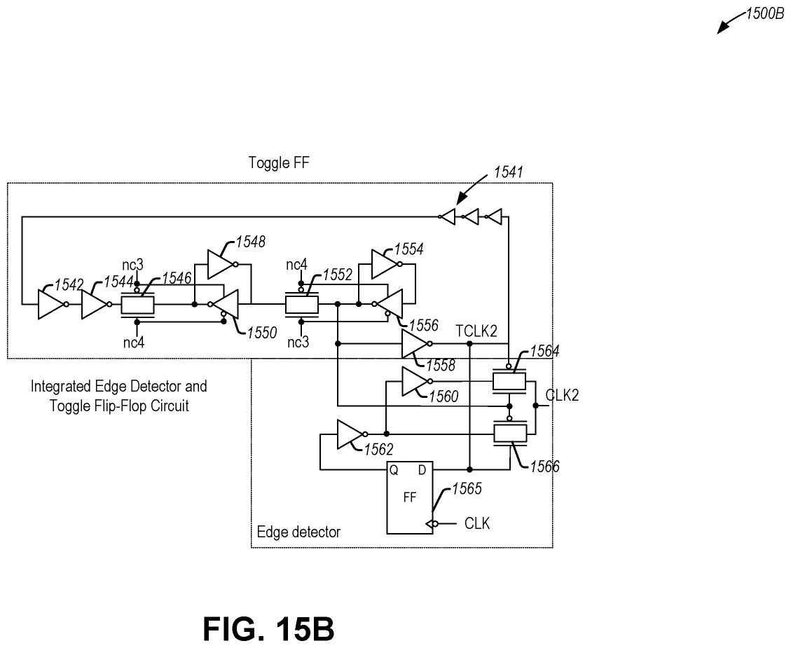

FIG. 15A is a diagram 1500A of a non-pulsed skewed clock pulse generation circuit to enable a non-overlapping pulsed clock with NAND-based pulse generators, in accordance with some embodiments. Referring to FIG. 15A, processing pipeline 1504 (e.g., pipeline 3) includes a NAND pulse generator 1506 generating clock signals nc3 and nc4 for latches 1508, 1510, . . . , 1512. The NAND pulse generator 1506 includes an inverter 1522 and a NAND gate 1524.

Processing pipeline 1502 (e.g., pipeline 2) includes a NAND pulse generator 1514 generating clock signals nc2 and nc1 for latches 1516, 1518, . . . , 1520. The NAND pulse generator 1514 includes an inverter 1526 and a NAND gate 1528.

Pipeline 3 is configured with a TFF 1530, FF 1532, and an XOR gate 1534 to generate clock CLK2 communicated to pipeline 2. Similarly, pipeline 2 is configured with a TFF 1536, FF 1538, and an XOR gate 1540 to generate clock CLK1 communicated to pipeline 1. An example TFF diagram is illustrated in FIG. 15B.

FIG. 15A also illustrates corresponding timing diagrams 1570, 1572, 1574, 1576, 1578, 1580, and 1582 of the clock signals used or generated by pipeline 3 and pipeline 2.

FIG. 15B is a diagram of a toggle flip-flop 1500B for generating one or more clock signals for the pulse generation circuit of FIG. 15A, in accordance with some embodiments. Referring to FIG. 15B, TFF 1500B (which can be the same as TFF 1530 or TFF 1536) includes inverters 1541, 1542, 1544, 1548, 1554, 1558, 1560, and 1562. TFF 1500B further includes transmission gates 1546, 1552, 1564, and 1566. TFF 1500B further includes FF 1565 and tri-state inverters 1550 and 1556.

The circuit illustrated in FIGS. 13A-13B uses NAND-based and XOR-based pulse generators in two successive pipeline stages. Using two different types of pulse generators may result in a clock skew difference between two pipeline stages and increase design complexity. In some aspects, the skewed clock generator illustrated in FIGS. 15A-15B adds a rising/falling edge detector in front of the TFF. This edge detector converts the falling and the rising edge of the skewed clock (TCLk2) generated by the TFF to a rising edge skewed clock signal CLK2. The pulse generator in pipeline stage 2 can now be a NAND-based pulse generator since the clock pulse can be created at the rising edge. This skewed clock signal CLK2 is not a pulsed signal and can be distributed without any pulse evaporation. The XOR circuit of the edge detector is integrated into the toggle flip-flop output inverter to minimize the added clock skew of the edge detector.

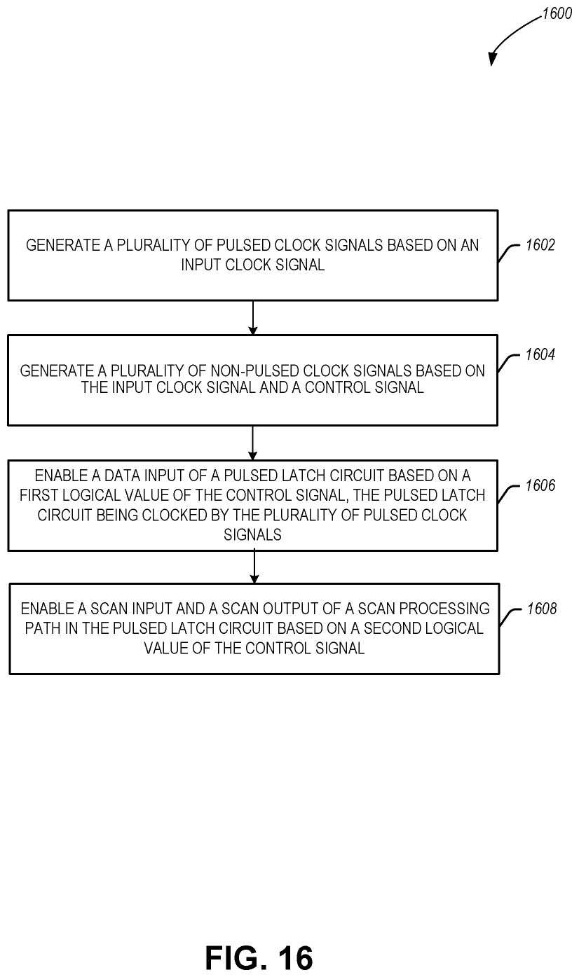

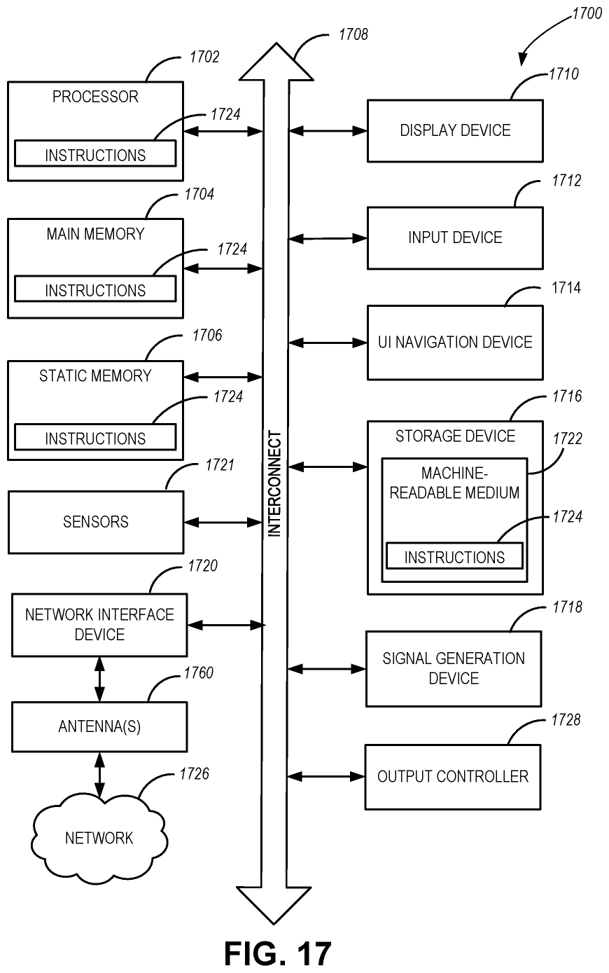

FIG. 16 is a flow diagram of an example method 1600 for configuring a pulsed latch circuit, in accordance with some embodiments. Referring to FIG. 16, method 1600 includes operations 1602, 1604, 1606, and 1608, which may be executed by an embedded controller or another processor of a computing device (e.g., hardware processor 1702 of machine 1700 illustrated in FIG. 17, which can include one or more of the circuits discussed in connection with FIGS. 1-15B). In some embodiments, one or more of the circuits discussed in connection with FIGS. 1-15B can perform the functionalities listed in FIG. 16, as well as in the examples listed below.

The following example operations can be configured based on the description of FIG. 6A.

At operation 1602, a plurality of pulsed clock signals are generated based on an input clock signal.

At operation 1604, a plurality of non-pulsed clock signals are generated based on the input clock signal and a control signal.

At operation 1606, a data input of a pulsed latch circuit is enabled based on a first logical value of the control signal. In some aspects, the pulsed latch circuit is clocked by the plurality of pulsed clock signals.

At operation 1608, a scan input and a scan output of a scan processing path in the pulsed latch circuit are enabled based on a second logical value of the control signal. The plurality of non-pulsed clock signals clocks the scan processing path.

FIG. 17 illustrates a block diagram of an example machine 1700 upon which any one or more of the techniques (e.g., methodologies) discussed herein may perform. In alternative embodiments, the machine 1700 may operate as a standalone device or may be connected (e.g., networked) to other machines. In a networked deployment, machine 1700 may operate in the capacity of a server machine, a client machine, or both in server-client network environments. In an example, machine 1700 may function as a peer machine in a peer-to-peer (P2P) (or other distributed) network environment. The machine 1700 may be a personal computer (PC), a tablet PC, a set-top box (STB), a personal digital assistant (PDA), a portable communications device, a mobile telephone, a smartphone, a web appliance, a network router, switch or bridge, or any other computing device capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations. The terms “machine,” “computing device,” and “computer system” are used interchangeably.

Machine (e.g., computer system) 1700 may include a hardware processor 1702 (e.g., a central processing unit (CPU), a graphics processing unit (GPU), a hardware processor core, or any combination thereof), a main memory 1704, and a static memory 1706, some or all of which may communicate with each other via an interlink (e.g., bus) 1708. In some aspects, the main memory 1704, the static memory 1706, or any other type of memory (including cache memory) used by machine 1700 can be configured based on the disclosed techniques or can implement the disclosed memory devices.

Specific examples of main memory 1704 include Random Access Memory (RAM) and semiconductor memory devices, which may include, in some embodiments, storage locations in semiconductors such as registers. Specific examples of static memory 1706 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; and CD-ROM and DVD-ROM disks.

Machine 1700 may further include a display device 1710, an input device 1712 (e.g., a keyboard), and a user interface (UI) navigation device 1714 (e.g., a mouse). In an example, the display device 1710, the input device 1712, and the UI navigation device 1714 may be a touchscreen display. The machine 1700 may additionally include a storage device (e.g., drive unit or another mass storage device) 1716, a signal generation device 1718 (e.g., a speaker), a network interface device 1720, and one or more sensors 1721, such as a global positioning system (GPS) sensor, compass, accelerometer, or other sensors. The machine 1700 may include an output controller 1728, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). In some embodiments, the hardware processor 1702 and/or instructions 1724 may comprise processing circuitry and/or transceiver circuitry.

The storage device 1716 may include a machine-readable medium 1722 on which one or more sets of data structures or instructions 1724 (e.g., software) embodying or utilized by any one or more of the techniques or functions described herein can be stored. Instructions 1724 may also reside, completely or at least partially, within the main memory 1704, within static memory 1706, or the hardware processor 1702 during execution thereof by the machine 1700. In an example, one or any combination of the hardware processor 1702, the main memory 1704, the static memory 1706, or the storage device 1716 may constitute machine-readable media.

Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

While the machine-readable medium 1722 is illustrated as a single medium, the term “machine-readable medium” may include a single medium or multiple media (e.g., a centralized or distributed database and/or associated caches and servers) configured to store instructions 1724.

An apparatus of the machine 1700 may be one or more of a hardware processor 1702 (e.g., a central processing unit (CPU), a graphics processing unit (GPU), a hardware processor core, or any combination thereof), a main memory 1704 and a static memory 1706, one or more sensors 1721, a network interface device 1720, one or more antennas 1760, a display device 1710, an input device 1712, a UI navigation device 1714, a storage device 1716, instructions 1724, a signal generation device 1718, and an output controller 1728. The apparatus may be configured to perform one or more of the methods and/or operations disclosed herein. The apparatus may be intended as a component of machine 1700 to perform one or more of the methods and/or operations disclosed herein and/or to perform a portion of one or more of the methods and/or operations disclosed herein. In some embodiments, the apparatus may include a pin or other means to receive power. In some embodiments, the apparatus may include power conditioning hardware.

The term “machine-readable medium” may include any medium that is capable of storing, encoding, or carrying instructions for execution by machine 1700 and that causes machine 1700 to perform any one or more of the techniques of the present disclosure or that is capable of storing, encoding, or carrying data structures used by or associated with such instructions. Non-limiting machine-readable medium examples may include solid-state memories and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks. In some examples, machine-readable media may include non-transitory machine-readable media. In some examples, machine-readable media may include machine-readable media that is not a transitory propagating signal.

The instructions 1724 may further be transmitted or received over a communications network 1726 using a transmission medium via the network interface device 1720 utilizing any one of several transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, a Long Term Evolution (LTE) family of standards, a Universal Mobile Telecommunications System (UMTS) family of standards, peer-to-peer (P2P) networks, among others.

In an example, the network interface device 1720 may include one or more physical jacks (e.g., Ethernet, coaxial, or phone jacks) or one or more antennas to connect to the communications network 1726. In an example, the network interface device 1720 may include one or more antennas 1760 to wirelessly communicate using at least one single-input multiple-output (SIMO), multiple-input multiple-output (MIMO), or multiple-input single-output (MISO) techniques. In some examples, the network interface device 1720 may wirelessly communicate using multiple-user MIMO techniques. The term “transmission medium” shall be taken to include any intangible medium that can store, encode, or carry instructions for execution by the machine 1700 and includes digital or analog communications signals or other intangible media to facilitate communication of such software.

Examples, as described herein, may include, or may operate on, logic or several components, modules, or mechanisms. Modules are tangible entities (e.g., hardware) capable of performing specified operations and may be configured or arranged in a particular manner. In an example, circuits may be arranged (e.g., internally or concerning external entities such as other circuits) in a specified manner as a module. In an example, the whole or part of one or more computer systems (e.g., a standalone, client, or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part, all, or any operation described herein. Considering examples in which modules are temporarily configured, each of the modules need not be instantiated at any one moment in time. For example, where the modules comprise a general-purpose hardware processor configured using the software, the general-purpose hardware processor may be configured as respective different modules at separate times. The software may accordingly configure a hardware processor, for example, to constitute a particular module at one instance of time and to constitute a different module at a different instance of time.

Some embodiments may be implemented fully or partially in software and/or firmware. This software and/or firmware may take the form of instructions contained in or on a non-transitory computer-readable storage medium. Those instructions may then be read and executed by one or more processors to enable the performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM), random access memory (RAM), magnetic disk storage media, optical storage media, flash memory, etc.

The above-detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof) or with respect to other examples (or one or more aspects thereof) shown or described herein.

Publications, patents, and patent documents referred to in this document are incorporated by reference herein in their entirety, as though individually incorporated by reference. In the event of inconsistent usage between this document and those documents so incorporated by reference, the usage in the incorporated reference(s) is supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc., are used merely as labels and are not intended to suggest a numerical order for their objects.

The embodiments as described above may be implemented in various hardware configurations that may include a processor for executing instructions that perform the techniques described. Such instructions may be contained in a machine-readable medium such as a suitable storage medium or a memory or other processor-executable medium.

The embodiments as described herein may be implemented in several environments, such as part of a system on chip, a set of intercommunicating functional blocks, or similar, although the scope of the disclosure is not limited in this respect.

Described implementations of the subject matter can include one or more features, alone or in combination, as illustrated below by way of examples.

Example 1 is a latch circuit including a NOR gate including a first input terminal to receive a scan input signal and a second input terminal to receive a control signal; a first transmission gate including a first input terminal coupled to an output terminal of the NOR gate, and a second input terminal and a third input terminal to receive at least one non-pulsed clock signal; a first inverter including an input terminal to receive a data input signal; and a second transmission gate including a first input terminal coupled to an output terminal of the first inverter, and a second input terminal and a third input terminal to receive at least one pulsed clock signal.

In Example 2, the subject matter of Example 1 includes a second inverter, including an input terminal coupled to an output terminal of the first transmission gate.

In Example 3, the subject matter of Example 2 includes a first tri-state inverter, including an output terminal coupled to the input terminal of the second inverter and a first input terminal coupled to an output terminal of the second inverter.

In Example 4, the subject matter of Example 3 includes subject matter where a second input terminal and a third input terminal of the first tri-state inverter receive the at least one pulsed clock signal.

In Example 5, the subject matter of Examples 3-4 includes a third transmission gate, including a first input terminal coupled to the output terminal of the second inverter, a second input terminal, and a third input terminal to receive the at least one non-pulsed clock signal.

In Example 6, the subject matter of Example 5 includes a third inverter, including an input terminal coupled to an output terminal of the third transmission gate, and a fourth inverter, including an input terminal coupled to an output terminal of the third inverter, and an output terminal coupled to a scan output terminal of the latch circuit.

In Example 7, the subject matter of Examples 5-6 includes a second tri-state inverter including an output terminal coupled to an output terminal of the second transmission gate and a first input terminal coupled to an output terminal of the third transmission gate, wherein a second input terminal and a third input terminal of the second tri-state inverter receive the at least one pulsed clock signal.

In Example 8, the subject matter of Example 7 includes a third tri-state inverter, including a first input terminal coupled to the output terminal of the second transmission gate and an output terminal coupled to an output terminal of the third transmission gate, wherein a second input terminal and a third input terminal of the third tri-state inverter receive the at least one non-pulsed clock signal.

In Example 9, the subject matter of Example 8 includes a third inverter, including an input terminal coupled to the output terminal of the second transmission gate and an output terminal coupled to a data output node of the latch circuit.

In Example 10, the subject matter of Examples 1-9 includes a processor, wherein the processor includes one or more of the NOR gate, the first transmission gate, the first inverter, and the second transmission gate.

In Example 11, the subject matter of Examples 1-10 includes one or more interconnects coupling two or more of the NOR gate, the first transmission gate, the first inverter, and the second transmission gate.

Example 12 is a method that includes generating a plurality of pulsed clock signals based on an input clock signal, generating a plurality of non-pulsed clock signals based on the input clock signal and a control signal, enabling a data input of a pulsed latch circuit based on a first logical value of the control signal, the plurality of pulsed clock signals clocks the pulsed latch circuit; and enabling a scan input and a scan output of a scan processing path in the pulsed latch circuit based on a second logical value of the control signal, the scan processing path being clocked by the plurality of non-pulsed clock signals.

In Example 13, the subject matter of Example 12 includes generating the plurality of pulsed clock signals and the plurality of non-pulsed clock signals at a NAND gate-based clock generator of the pulsed latch circuit.

In Example 14, the subject matter of Example 13 includes supplying the plurality of pulsed clock signals to a toggle flip-flop and a first processing pipeline, including the pulsed latch circuit.

In Example 15, the subject matter of Example 14 includes generating a toggle clock signal at the toggle flip-flop based on the plurality of pulsed clock signals.

In Example 16, the subject matter of Example 15 includes generating using an XOR gate-based clock generator of a second processing pipeline, a second plurality of pulsed clock signals, and providing the second plurality of pulsed clock signals to one or more latch circuits within the second processing pipeline.

Example 17 is an apparatus including a NAND gate-based clock generator to generate a plurality of pulsed clock signals and a plurality of non-pulsed clock signals based on an input clock signal and a control signal; a scan processing path including a NOR gate receiving the control signal and a scan input signal, and a first transmission gate clocked by the plurality of non-pulsed clock signal; and a data processing path including a second transmission gate clocked by the plurality of pulsed clock signals, the control signal to enable one of the scan processing path or the data processing path via an output of the NOR gate.

In Example 18, the subject matter of Example 17 includes subject matter where the NAND gate-based clock generator further includes a first NAND gate to receive the input clock signal and output a first pulsed clock signal of the plurality of pulsed clock signals and a second NAND gate to receive an inverted version of the control signal and generate a first non-pulsed clock signal of the plurality of non-pulsed clock signals.

In Example 19, the subject matter of Examples 17-18 includes a keeper bypass scan multiplexer circuit configured within the data processing path, the keeper bypass scan multiplexer circuit including a first tri-state inverter including an input terminal coupled to the scan processing path, and an output terminal coupled to an output terminal of the second transmission gate.

In Example 20, the subject matter of Example 19 includes subject matter where the keeper bypass scan multiplexer circuit includes a second tri-state inverter including an output terminal coupled to the input terminal of the first tri-state inverter and an input terminal coupled to the output terminal, of the second transmission gate.

Example 21 is at least one machine-readable medium including instructions that, when executed by processing circuitry, cause the processing circuitry to perform operations to implement any of Examples 1-20.

Example 22 is an apparatus comprising means to implement any of Examples 1-20.

Example 23 is a system to implement any of Examples 1-20.

Example 24 is a method to implement any of Examples 1-20.

The above description is intended to be illustrative and not restrictive. For example, the above-described examples (or one or more aspects thereof) may be used in combination with others. Other embodiments may be used, such as by one of ordinary skill in the art upon reviewing the above description. The abstract is to allow the reader to ascertain the nature of the technical disclosure quickly. It is submitted with the understanding that it will not be used to interpret or limit the scope or meaning of the claims. Also, in the above Detailed Description, various features may be grouped to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined regarding the appended claims, along with the full scope of equivalents to which such claims are entitled.

What is claimed is:

1. A latch circuit comprising:
a NOR gate including a first input terminal to receive a scan input signal and a second input terminal to receive a control signal;
a first transmission gate including a first input terminal coupled to an output terminal of the NOR gate, and a second input terminal and a third input terminal to receive at least one non-pulsed clock signal;
a first inverter including an input terminal to receive a data input signal; and
a second transmission gate including a first input terminal coupled to an output terminal of the first inverter, and a second input terminal and a third input terminal to receive at least one pulsed clock signal.

2. The latch circuit of claim 1, further comprising:
a second inverter including an input terminal coupled to an output terminal of the first transmission gate.

3. The latch circuit of claim 2, further comprising:
a first tri-state inverter including an output terminal coupled to the input terminal of the second inverter and a first input terminal coupled to an output terminal of the second inverter.

4. The latch circuit of claim 3, wherein a second input terminal and a third input terminal of the first tri-state inverter receive the at least one pulsed clock signal.

5. The latch circuit of claim 3, further comprising:
a third transmission gate including a first input terminal coupled to the output terminal of the second inverter, and a second input terminal and a third input terminal to receive the at least one non-pulsed clock signal.

6. The latch circuit of claim 5, further comprising:
a third inverter including an input terminal coupled to an output terminal of the third transmission gate; and
a fourth inverter including an input terminal coupled to an output terminal of the third inverter, and an output terminal coupled to a scan output terminal of the latch circuit.

7. The latch circuit of claim 5, further comprising:
a second tri-state inverter including an output terminal coupled to an output terminal of the second transmission gate, and a first input terminal coupled to an output terminal of the third transmission gate, wherein a second input terminal and a third input terminal of the second tri-state inverter receive the at least one pulsed clock signal.

8. The latch circuit of claim 7, further comprising:
a third tri-state inverter including a first input terminal coupled to the output terminal of the second transmission gate, and an output terminal coupled to an output terminal of the third transmission gate, wherein a second input terminal and a third input terminal of the third tri-state inverter receive the at least one non-pulsed clock signal.

9. The latch circuit of claim 8, further comprising:
a third inverter including an input terminal coupled to the output terminal of the second transmission gate and an output terminal coupled to a data output node of the latch circuit.

10. The latch circuit of claim 1, further comprising a processor, and wherein the processor includes one or more of the NOR gate, the first transmission gate, the first inverter, and the second transmission gate.

11. The latch circuit of claim 10, further comprising:
one or more interconnects coupling two or more of the NOR gate, the first transmission gate, the first inverter, and the second transmission gate.

12. The latch circuit of claim 11, further comprising:
a system-on-a-chip (SoC) including the processor and at least one memory, the at least one memory coupled to the processor via the one or more interconnects.

13. The latch circuit of claim 12, further comprising:
an antenna coupled to the SoC.

14. A method comprising:
generating a plurality of pulsed clock signals based on an input clock signal;
generating a plurality of non-pulsed clock signals based on the input clock signal and a control signal;
enabling a data input of a pulsed latch circuit based on a first logical value of the control signal, the pulsed latch circuit being clocked by the plurality of pulsed clock signals; and
enabling a scan input and a scan output of a scan processing path in the pulsed latch circuit based on a second logical value of the control signal, the scan processing path being clocked by the plurality of non-pulsed clock signals.

15. The method of claim 14, further comprising:
generating the plurality of pulsed clock signals and the plurality of non-pulsed clock signals at a NAND gate-based clock generator of the pulsed latch circuit.

16. The method of claim 15, further comprising:
supplying the plurality of pulsed clock signals to a toggle flip-flop and a first processing pipeline including the pulsed latch circuit;
generating at the toggle flip-flop, a toggle clock signal based on the plurality of pulsed clock signals;
generating using an XOR gate-based clock generator of a second processing pipeline, a second plurality of pulsed clock signals; and
providing the second plurality of pulsed clock signals to one or more latch circuits within the second processing pipeline.

17. An apparatus comprising:
a NAND gate-based clock generator to generate a plurality of pulsed clock signals and a plurality of non-pulsed clock signals based on an input clock signal and a control signal;
a scan processing path including a NOR gate receiving the control signal and a scan input signal, and a first transmission gate clocked by the plurality of non-pulsed clock signal; and
a data processing path including a second transmission gate clocked by the plurality of pulsed clock signals, the control signal to enable one of the scan processing path or the data processing path via an output of the NOR gate.

18. The apparatus of claim 17, wherein the NAND gate-based clock generator further comprises:
a first NAND gate to receive the input clock signal and output a first pulsed clock signal of the plurality of pulsed clock signals; and
a second NAND gate to receive an inverted version of the control signal and generate a first non-pulsed clock signal of the plurality of non-pulsed clock signals.

19. The apparatus of claim 17, further comprising a keeper bypass scan multiplexer circuit configured within the data processing path, the keeper bypass scan multiplexer circuit comprising:
a first tri-state inverter including an input terminal coupled to the scan processing path and an output terminal coupled to an output terminal of the second transmission gate.

20. The apparatus of claim 19, wherein the keeper bypass scan multiplexer circuit comprises:
a second tri-state inverter including an output terminal coupled to the input terminal of the first tri-state inverter and an input terminal coupled to the output terminal of the second transmission gate.
